(19) United States
(12) Patent Application Publication
(10) Pub. No.: US 2011/0003420 A1
(43) Pub. Date: Jan. 6, 2011

(54) Fabrication method of gallium nitride-based compound semiconductor

(75) Inventors: Miin-Jang Chen, Taipei City (TW); Sheng-Fu Yu, Chiayi City (TW); Ray-Ming Lin, Xinzhuang City (TW); Wen-Ching Hsu, Hsinchu (TW); Szu-Hua Ho, Hsinchu (TW)

Correspondence Address: HUDAK, SHUNK & FARINE, CO., L.P.A., 2020 FRONT STREET, SUITE 307, CUYAHOGA FALLS, OH, 44221, US

(73) Assignee: SINO-AMERICAN SILICON PRODUCTS INC., HSINCHU (TW)

(21) Appl. No.: 12/592,926

(22) Filed: Dec. 4, 2009

(30) Foreign Application Priority Data
Jul. 2, 2009 (TW) 098122482

(51) Int. Cl. H01L 21/20; H01L 33/00

(52) U.S. Cl. 438/47; 438/478; 257/E21.09; 257/E33.008

(57) ABSTRACT

The present invention discloses a method for fabricating gallium nitride(GaN)-based compound semiconductors. Particularly, this invention relates to a method of forming a transition layer on a zinc oxide (ZnO)-based semiconductor layer by the steps of forming a wetting layer and making the wetting layer nitridation. The method not only provides a function of protecting the ZnO-based semiconductor layer, but also uses the transition layer as a buffer layer for a following epitaxial growth of a GaN-based semiconductor layer, and thus, the invention may improve the crystal quality of the GaN-based semiconductor layer effectively.

### BACKGROUND OF THE INVENTION

1. Field of the Invention

The present invention relates to a method for fabricating GaN-based compound semiconductor, in particular to a fabrication method that inserts a transition layer between a GaN-based semiconductor layer and a ZnO-based semiconductor layer to improve the crystal quality of the GaN-based semiconductor layer.

2. Description of the Related Art

Currently, according to the available light emitting devices, the GaN-based semiconductor material is a very important wide bandgap material which is applied to red, blue, and ultraviolet light emitting devices. However, due to the technical bottleneck of directly forming a bulk GaN compound semiconductor still cannot be overcome, and thus, the large-sized substrate cannot be achieved for mass productions to lower the manufacturing cost effectively. Although the conventional way of using sapphire or silicon carbide as a substrate to grow a GaN-based layer is used extensively and commercialized, yet the issue of lattice mismatch between the aforementioned substrates and GaN-based layer still exists, and thus the GaN-based layer fabricated by the conventional method still has a relatively high defect density which will cause the light emission efficiency and electron mobility unable to be enhanced in the applications of light emitting devices specially. Therefore, the conventional method has some drawbacks.

To overcome the drawbacks of the aforementioned fabrication method of GaN-based layer, U.S. Pat. No. 6,252,261 disclosed a method of reducing the defect density by epitaxial lateral overgrowth (ELOG), and the method firstly utilizes both the photolithography and etching processes to form a patterned silicon dioxide layer on a sapphire substrate, and then controls the complicated selectively epitaxy mechanism of a metal organic chemical vapor deposition to grow an over 10 μm-thick gallium nitride (GaN)-based layer for achieving the effect of reducing the defect density to a level below 1×10⁷ cm⁻². However, this method has the drawback of incurring a higher cost. Furthermore, U.S. Pat. No. 7,125,736 disclosed an epitaxial lateral overgrowth (ELOG) technology by using a patterned sapphire substrate. Although this patented technology may reduce the defect density below 1×10⁸ cm⁻² by a thinner epitaxial layer, yet it cannot be easily controlled about the uniformity and the density of patterns on a sapphire surface, and thus the yield rate is difficult to control.

Furthermore, as disclosed in U.S. Pat. No. 5,173,751, a GaN-based light emitting diode (LED) structure of forming an aluminum gallium nitride (AlGaN) layer or an aluminum gallium nitride phosphate (AlGaNP) layer lattice is matched to a zinc oxide (ZnO) substrate. Since both the ZnO and GaN are wurtzite structures belong to the hexagonal crystal systems, and the lattice constants for ZnO are (a=3.25 Å; c=5.2 Å) and for GaN are (a=3.187 Å; c=5.188 Å). The lattice constant of compound semiconductor may be adjusted and matched to zinc oxide by adding appropriate compositions of phosphor, indium, and aluminum into the GaN, the defect density will be reduced. Therefore, ZnO is used as the substrate of depositing the GaN layer with the advantage of reducing the defect density.

As disclosed in a journal published in Applied Physics Letters vol. 61 (1992) p. 2688 by T. Detchprohm et al, a ZnO layer is formed on a sapphire substrate as a buffer layer and a GaN layer is grown on the ZnO buffer layer by hydride vapor phase epitaxy (HVPE). The GaN layer has high-quality indications with background concentration is 9×10¹⁵˜4×10¹⁶ cm⁻³ and mobility is 420˜520 cm² V⁻¹S⁻¹ measured at room temperature, respectively. As disclosed in Journal of Crystal Growth vol. 225 (2001) p. 150 by P. Chen et al, an aluminum layer is formed on a silicon substrate as a wetting layer by using a trimethylaluminum (TMAl) reaction precursor, and then introduces ammonia precursor to nitrify the wetting layer into aluminum nitride (AlN) as a buffer layer, and a GaN layer is grown on the AlN buffer layer. The GaN layer has high-quality indications with background concentration of approximately 1.3×10¹⁷ cm⁻³ and mobility is of approximately 210 cm²V⁻¹S⁻¹ measured at room temperature, respectively.

In a method of forming a GaN-based layer on a silicon substrate by epitaxial growth as disclosed in U.S. Pat. No. 7,001,791, a ZnO layer is formed on the silicon substrate as a buffer layer, a first GaN-based layer is grown at the growth temperature below 600° C., and a second GaN-based layer is grown on the first GaN-based layer at a growth temperature above 600° C. This patent also discloses another method that uses triethylgallium (TEG) to treat the surface of the ZnO buffer layer and then introduces ammonia precursor to make nitridation on the treated surface before growing the first GaN-based layer at a temperature below 600° C., and then grows the second GaN-based layer above 600° C.

As disclosed in Journal of Crystal Growth vol. 310 (2008) p. 4891 by R. Paszkiewicz et al, a ZnO layer is formed on a silicon substrate as a buffer layer, and then the GaN and AlN multilayers structure is formed on the ZnO buffer layer at gradually-changing temperature; besides, GaN layer is formed on the multilayers structure at gradually-changing temperature over 1000° C., so that it may get a high-quality GaN film layer over 2 μm thickness without any cracks by epitaxial growth.

In summation of the aforementioned prior arts, the growth temperature needs to maintain over 1000° C. for achieving a high crystal quality of the GaN layer. If zinc oxide (ZnO) is used for making the substrate or the buffer layer, maintaining the stability of the atomic layer on the surface of zinc oxide (ZnO) is helpful to achieve a high-quality gallium nitride (GaN) layer. Therefore, the inventor of the present invention based on years of experience in the LED related industry to conduct extensive researches and experiments, and finally provided a fabrication method of improving the crystal quality of GaN layers to enhance the luminaire efficiency of a GaN light emitting diode (LED).

### SUMMARY OF THE INVENTION

It is a primary objective of the present invention to provide a fabrication method of a GaN-based compound semiconductor, particularly a fabrication method of forming and superimposing the wetting layer on a ZnO-based semiconductor layer and nitrifying the wetting layer many times to form a transition layer, so as to improve the crystal quality of a continuously growed GaN-based semiconductor layer.

Another objective of the present invention is to provide a fabrication method of GaN-based compound semiconductor, particularly a fabrication method of forming a wetting layer on a ZnO-based semiconductor layer at the first temperature, and then nitrifying the wetting layer at the second temperature many times to form a transition layer, so as to improve the crystal quality of the GaN-based semiconductor layer, wherein the second temperature is not less than the first temperature.

A further objective of the present invention is to provide a fabrication method of a GaN-based compound semiconductor, particularly a fabrication method of forming a first transition layer on a ZnO-based semiconductor layer at a first temperature, and then forming a second transition layer at a second temperature, so as to improve the crystal quality of the continuously grown GaN-based semiconductor layer, wherein the temperature of forming the second transition layer is no less than the temperature of forming the first transition layer.

Another objective of the present invention is to provide a fabrication method of a GaN-based compound semiconductor, particularly a fabrication method of forming and superimposing different wetting layers on a ZnO-based semiconductor layer and nitrifying the wetting layers many times to form a transition layer, so as to improve the crystal quality of the continuously grown GaN-based semiconductor layer.

Another objective of the present invention is to provide a fabrication method of GaN-based compound semiconductor, particularly a fabrication method of forming a transition layer by the steps of forming a wetting layer on a ZnO-based semiconductor layer and nitrifying the wetting layer, and the transition layer not only protects the surface of the ZnO-based semiconductor layer, but also provides a buffer layer to improve the crystal quality of a continuously grown GaN-based semiconductor layer.

### BRIEF DESCRIPTION OF THE DRAWINGS

FIG. 1 is a flow chart of a fabrication method of the present invention;

FIG. 2 is a flow chart of another fabrication method of the present invention;

FIG. 3 is a schematic view of a structure in accordance with a first preferred embodiment of the present invention;

FIG. 4 is a schematic view of a structure in accordance with a second preferred embodiment of the present invention;

FIG. 5 is a schematic view of a structure in accordance with a third preferred embodiment of the present invention;

FIG. 6 is a schematic view of a structure in accordance with a fourth preferred embodiment of the present invention;

FIG. 7 is a schematic view of a structure in accordance with a fifth preferred embodiment of the present invention;

FIG. 8 is a schematic view of a structure in accordance with a sixth preferred embodiment of the present invention;

FIG. 9 shows an x-ray diffraction (XRD) spectrum in accordance with a first preferred embodiment of the present invention;

FIG. 10 shows a transmission electron microscope (TEM) photo of the cross-section of a first preferred embodiment of the present invention;

FIG. 11 shows a structure of an LED application having a ZnO-based semiconductor layer in accordance with a preferred embodiment of the present invention; and

FIG. 12 shows an electroluminescent spectrum of an LED application in accordance with a preferred embodiment of the present invention.

### DETAILED DESCRIPTION OF THE PREFERRED EMBODIMENTS

The technical measures taken for achieving the aforementioned objectives, and the effects, structures and characteristics of the present invention will become apparent in the following detailed description with reference to the accompanying drawings.

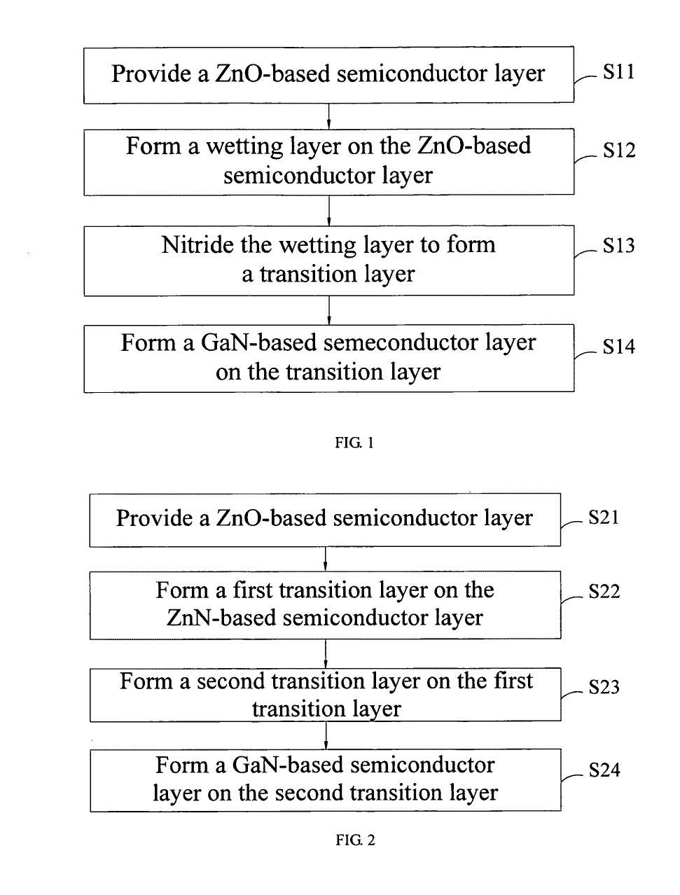

With reference to FIG. 1 for a flow chart of a fabrication method in accordance with the present invention, the fabrication method comprises the following steps:

Step S11: Provide a ZnO-based semiconductor layer;

Step S12: Form a wetting layer on the ZnO-based semiconductor layer;

Step S13: Nitrify the wetting layer to form a transition layer; and

Step S14: Form a GaN-based semiconductor layer on the transition layer.

Wherein, Step S11 further comprises the steps of forming a ZnO-based semiconductor layer on a different substrate, and then repeating Steps S12 and S13 to form and superimpose a wetting layer and nitrify the wetting layer for many times, and Step S14 further comprises many stages with different epitaxial growth conditions for forming the GaN-based semiconductor layer.

With reference to FIG. 2 for a flow chart of another fabrication method in accordance with the present invention, the fabrication method comprises the following steps:

Step S21: Provides a ZnO-based semiconductor layer;

Step S22: Form a first wetting layer on the ZnO-based semiconductor layer, and nitrify the first wetting layer to form a first transition layer;

Step S23: Form a second wetting layer on the first transition layer and nitrify the second wetting layer to form a second transition layer; and

Step S24: Form a GaN-based semiconductor layer on the second transition layer.

Step S21 further comprises the steps of forming a ZnO-based semiconductor layer on a different substrate, and repeating Steps S22 and S23 to form a multi-superimposed structure of a first transition layer and a second transition layer, and Step S14 further comprises many stages with different epitaxial growth conditions for forming the GaN-based semiconductor layer.

To make our examiner to understand the steps, technical measures and structure of the present invention, we use preferred embodiments together with the aforementioned flow charts for the description of the method and structure of the invention as follows.

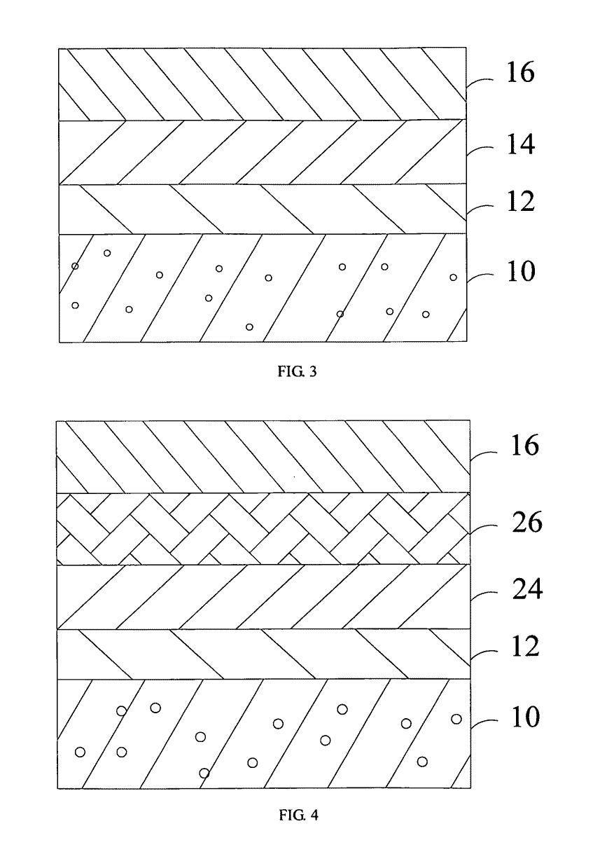

With reference to FIG. 3 for a schematic view of a structure in accordance with a first preferred embodiment of the present invention, the structure comprises a substrate 10, a ZnO-based semiconductor layer 12, a transition layer 14 and a GaN-based semiconductor layer 16, wherein the substrate 10 is the one selected from the group consisting of sapphire, silicon carbide, magnesium oxide, gallium oxide, lithium gallium oxide, lithium aluminum oxide, spinel, silicon, germanium, gallium arsenide, gallium phosphide, glass and zirconium diboride. The ZnO-based semiconductor layer 12 is formed on the substrate 10 by atomic layer epitaxy, chemical vapor phase epitaxy, molecular beam epitaxy, pulse laser deposition or radio frequency sputtering. The ZnO-based semiconductor layer 12 has the thickness of approximately 10 nm˜500 nm. The transition layer 14 is formed by a method as shown in the flow chart of FIG. 1. In Step S12, the substrate 10 with a ZnO-based semiconductor layer 12 is put into a metal organic chemical vapor deposition reaction chamber and nitrogen gas is passed into the reaction chamber until the temperature of the reaction chamber rises to 550° C. and holds for approximately 5 minutes, and then a trimethylaluminum reaction precursor is passed onto the ZnO-based semiconductor layer 12 for approximately 15 seconds to form a wetting layer. In Step S13, the supply of trimethylaluminum reaction precursor is stopped. After the temperature of the reaction chamber rises to 850° C., it holds for approximately one minute, ammonia gas is introduced for approximately 30 seconds to nitride the wetting layer. Then the supply of ammonia gas is disconnected, and after the temperature of the reaction chamber drops to 550° C. and remains stable for approximately one minute. Steps S12 and S13 are repeated sequentially 30 times. The reaction precursor used in Step S12 may be trimethylgallium, trimethylindium, triethylaluminum, triethylgallium or triethylalindium, and the reaction precursor used in Step S13 may be dimethylhydrazine or tert-butylhydrazine. The GaN-based semiconductor layer 16 is composed of BAlInGaNP or BAlInGaNAs. The epitaxial growth condition of Step S14 includes a temperature between 850˜1050° C. A reaction precursor (which is betrimethyl X, and X stands for an element of Group V in the periodic table), ammonia gas and hydrogen phosphide are introduced to form a GaN-based semiconductor layer with a thickness of 1˜4 μm. The step is similar to the prior art, and another similar method further divides the step into two steps: forming a GaN-based semiconductor layer with a thickness of 1˜2 μm at 850˜950° C. and another GaN-based semiconductor layer with a thickness of 1˜2 μm at 950˜1050° C., respectively.

With reference to FIG. 4 for a schematic view of a structure in accordance with a second preferred embodiment of the present invention, the structure comprises a substrate 10, a ZnO-based semiconductor layer 12, a first transition layer 24, a second transition layer 26 and a GaN-based semiconductor layer 16, wherein the substrate 10, ZnO-based semiconductor layer 12 and GaN-based semiconductor layer 16 are the same as those selected by the first preferred embodiment. The reaction precursor for forming the transition layer is the same as one of those selected by the first preferred embodiment, and the temperature of forming the second transition layer 26 is not less than the temperature of forming the first transition layer 24. The method of forming the transition layer is described as follows. In Step S21, the substrate 10 having a ZnO-based semiconductor layer 12 is put into a metal organic chemical vapor deposition reaction chamber and the nitrogen gas is also passed into the reaction chamber. In Step S22, the temperature of the reaction chamber rises to 550° C. and holds for approximately 5 minutes, and then a trimethylaluminum reaction precursor is introduced onto the ZnO-based semiconductor layer 12 for approximately 15 seconds to form a wetting layer, and then the supply of trimethylaluminum reaction precursor is stopped, and a dimethylhydrazine reaction precursor is introduced for approximately 30 seconds to nitride the wetting layer, and Step 22 is repeated for 15 times to form a first transition layer 24. In Step S23, the temperature of the reaction chamber rises to 850° C. and holds for approximately 5 minutes, and then a trimethylaluminum reaction precursor is passed onto the ZnO-based semiconductor layer 12 for approximately 15 seconds to form a wetting layer, and then the supply of trimethylaluminum reaction precursor is stopped, and a dimethylhydrazine reaction precursor is introduced for approximately 30 seconds to nitrify the wetting layer, and Step 23 is repeated for 15 times to form a second transition layer 26.

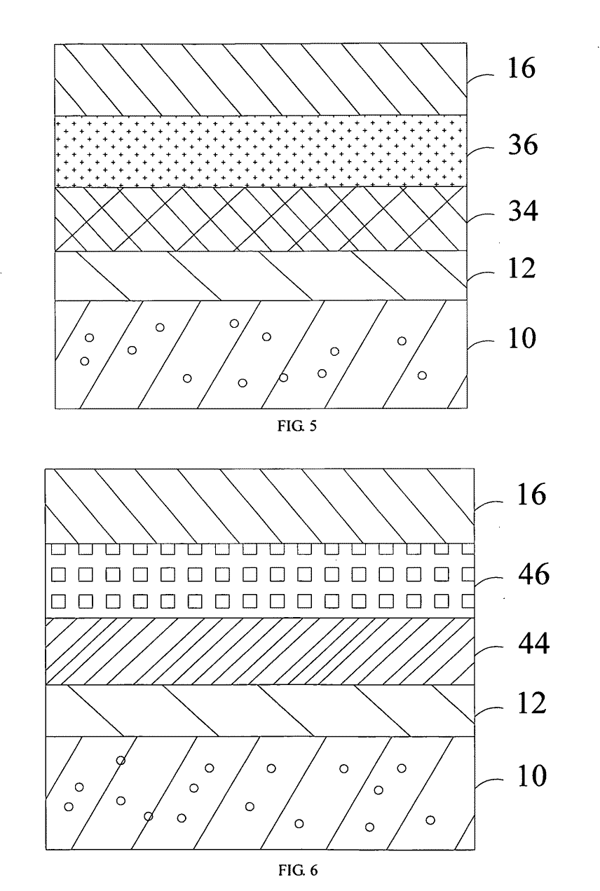

With reference to FIG. 5 for a schematic view of a structure in accordance with a third preferred embodiment of the present invention, the structure comprises a substrate 10, a ZnO-based semiconductor layer 12, a first transition layer 34, a second transition layer 36 and a GaN-based semiconductor layer 16, wherein the substrate 10, ZnO-based semiconductor layer 12 and GaN-based semiconductor layer 16 are the same as those selected by the first preferred embodiment, and the reaction precursor for forming the transition layer is the same as one of those selected by the first preferred embodiment, and the way of forming the first transition layer 34 is the same as Step S22 of the second preferred embodiment, and the method of forming the second transition layer 36 includes the steps of completing the first transition layer 34, maintaining the same condition of the reaction chamber at 850° C., introducing a trimethylgallium reaction precursor onto the first transition layer 34 for approximately 15 seconds to form a wetting layer, stopping the supply of trimethylgallium reaction precursor, introducing a dimethylhydrazine reaction precursor for approximately 30 to nitrify the wetting layer, and repeating the steps for 15 times to form a second transition layer 36.

With reference to FIG. 6 for a schematic view of a structure in accordance with a fourth preferred embodiment of the present invention, the structure comprises a substrate 10, a ZnO-based semiconductor layer 12, a first transition layer 44, a second transition layer 46 and a GaN-based semiconductor layer 16, wherein the substrate 10, ZnO-based semiconductor layer 12 and GaN-based semiconductor layer 16 are the same as those selected by the first preferred embodiment, and the reaction precursor for forming the transition layer is one of those selected by the first preferred embodiment, and the ways of forming the first transition layer 44 and the second transition layer 46 are the same as the second preferred embodiment, except that the reaction precursor used in Step S23 is changed to trimethylgallium for forming the second transition layer 46.

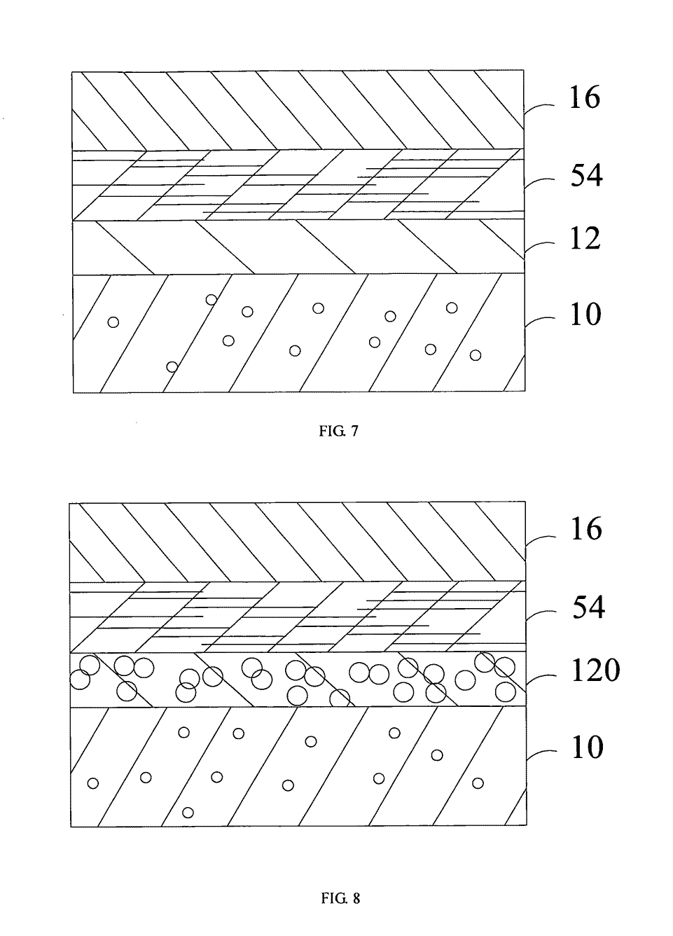

With reference to FIG. 7 for a schematic view of a structure in accordance with a fifth preferred embodiment of the present invention, the structure comprises a patterned substrate 10, a ZnO-based semiconductor layer 12, a first transition layer 54 and a GaN-based semiconductor layer 16, wherein the ZnO-based semiconductor layer 12 and GaN-based semiconductor layer 16 are the same as those selected by the first preferred embodiment, and the reaction precursor for forming the transition layer is one of those selected by the first preferred embodiment, and the method of forming the first transition layer 54 is the same as the second preferred embodiment. A second transition layer can be formed after the first transition layer 54 is formed, and the method of forming the second transition layer is the same as that of forming the second transition layers 26, 36, 46 of the second to fourth preferred embodiments.

With reference to FIG. 8 for a schematic view of a structure in accordance with a sixth preferred embodiment of the present invention, the structure comprises a substrate 10, a patterned ZnO-based semiconductor layer 120, a first transition layer 54 and a GaN-based semiconductor layer 16, wherein the substrate 10 and GaN-based semiconductor layer 16 are the same as those selected by the first preferred embodiment, and the reaction precursor for forming the transition layer is the same as the one selected by the first preferred embodiment, and the method of forming the first transition layer 54 is the same as the second preferred embodiment. A second transition layer can be formed after the first transition layer 54 is formed, and the method of forming the second transition layer is the same as that of forming the second transition layers 26, 36, 46 of the second to fourth preferred embodiments.

FIG. 9 shows an x-ray diffraction (XRD) spectrum in accordance with a first preferred embodiment of the present invention.

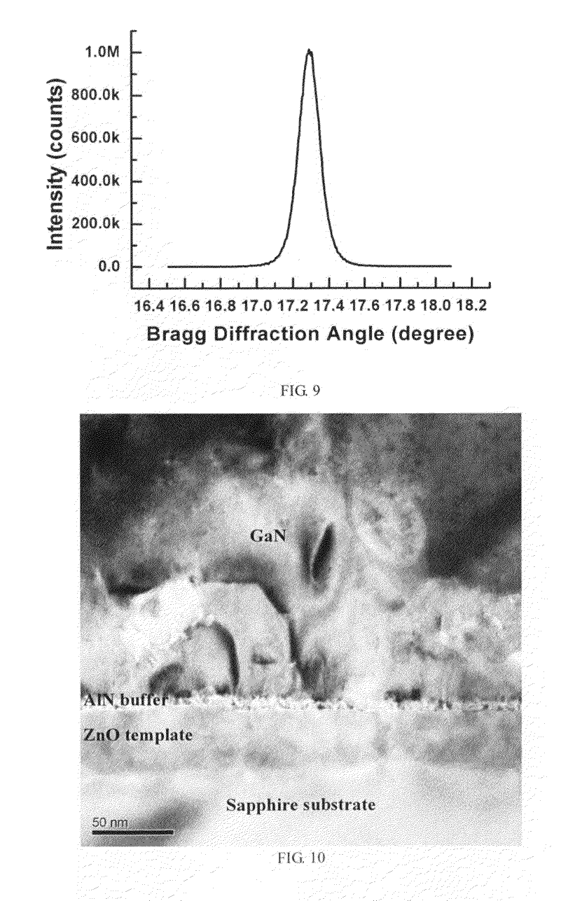

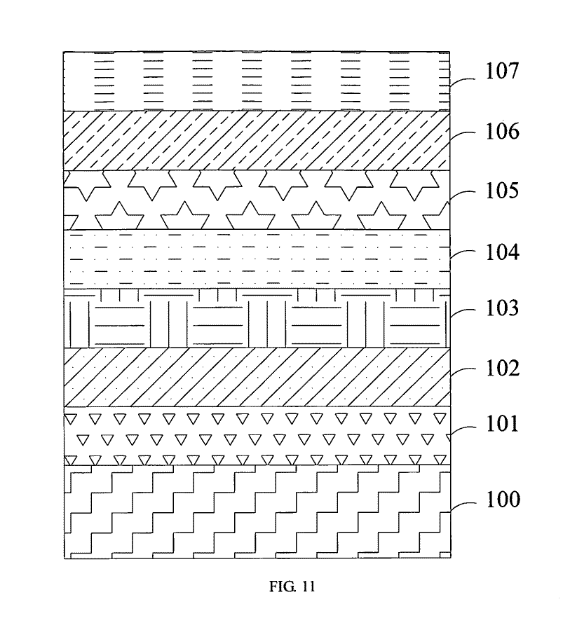

FIG. 10 shows a transmission electron microscope (TEM) photo of the cross-section of a first preferred embodiment of the present invention.

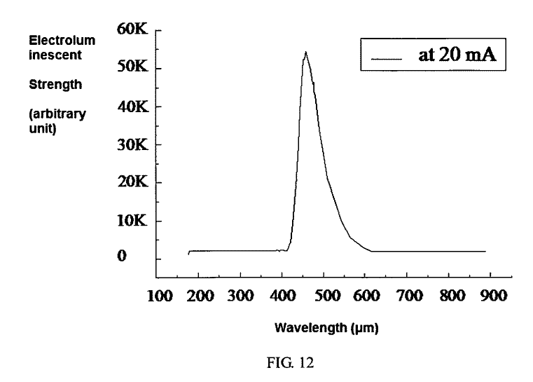

With reference to FIG. 11 for a structure of an LED application having a ZnO-based semiconductor layer in accordance with a preferred embodiment of the present invention, the structure comprises a sapphire substrate 100, a ZnO-based semiconductor layer 101, a transition layer 102, a non-doped GaN-based semiconductor layer 103, a N-type doped GaN ohmic contact layer 104, an light emitting layer of InGaN-based multiple quantum well structure 105, a P-type doped AlGaN cladding layer 106 and a P-type doped GaN ohmic contact layer 107. The method of forming the aforementioned structure is described as follows. First, the ZnO-based semiconductor layer 101 with the thickness of 180 nm is formed on the sapphire substrate 100 by atomic layer epitaxy, and then the sapphire substrate 100 with the ZnO-based semiconductor layer 101 is put into a metal organic chemical vapor deposition reaction chamber, and the transition layer 102 is formed according to the methods of forming the first and second transition layer as described in the second preferred embodiment, and then a reaction precursor such as ammonia gas and trimethylgallium is introduced into the reaction chamber at a temperature of 850° C. to form the non-doped GaN-based semiconductor layer having a thickness of 1 μm, and then the temperature of the reaction chamber rises to 980° C. to form another non-doped GaN-based semiconductor layer having a thickness of 1 μm, so as to complete forming the non-doped GaN-based semiconductor layer 103. And then, the temperature of the reaction chamber rises to 1030° C., and a silane-doped reaction precursor is introduced to form the Si-doped GaN ohmic contact layer 104 having a thickness of 3 μm. The supply of reaction precursor is stopped, and only ammonia gas and nitrogen gas are supplied into the reaction chamber. Now, the temperature of the reaction chamber drops to 800° C., and trimethylgallium and ammonia gas reaction precursors are introduced to form a GaN barrier layer having a thickness of 12.5 nm. The same conditions are maintained, while the trimethylindium and trimethylgallium and ammonia gas reaction precursors are introduced to form an InGN quantum well having a thickness of 2.5 nm. The steps are repeated many times to form a light emitting layer 105 with a InGaN-based multiple quantum well structure. The supply of reaction precursor is stopped, and only ammonia gas and nitrogen gas are supplied to the reaction chamber now. The nitrogen gas is changed to hydrogen gas while the temperature is rising to 980° C. After the temperature and flow becomes steady, biscyclopentadienyl magnesium, trimethylaluminum and trimethylgallium reaction precursors are introduced to form the P-type doped AlGaN cladding layer 106 having a thickness of 35 nm. Finally, the supply of trimethylaluminum is stopped to form the P-type doped GaN ohmic contact layer 107 having a thickness of 0.25 μm. The aforementioned epitaxial structure having a single crystalline ZnO-based is provided for an LED application in accordance with a preferred embodiment of the present invention, and then a conventional lateral-electrode process can be used for completing the manufacture of a GaN light emitting diode. FIG. 12 shows an electroluminescence spectrum of an LED application in accordance with a preferred embodiment of the present invention.

While the invention has been described by means of specific embodiments, numerous modifications and variations could be made thereto by those skilled in the art without departing from the scope and spirit of the invention set forth in the claims.

What is claimed is:

1. A fabrication method of gallium nitride (GaN)-based compound semiconductors, comprising the steps of:
providing a zinc oxide (ZnO)-based semiconductor layer;
forming a wetting layer on the ZnO-based semiconductor layer;
nitrifying the wetting layer;
repeating the steps of forming the wetting layer and nitrifying the wetting layer many times to form a transition layer; and
forming a GaN-based semiconductor layer on the transition layer.

2. The fabrication method of claim 1, wherein the wetting layer is formed by using a reaction precursor selected from the group consisting of trimethylaluminum, trimethylgallium, trimethylindium, triethylaluminum, triethylgallium and triethylalindium.

3. The fabrication method of claim 1, wherein the wetting layer is nitrified by using a reaction precursor selected from the group consisting of ammonia gas, dimethylhydrazine and tert-butylhydrazine.

4. The fabrication method of claim 1, wherein the transition layer is formed at a temperature not greater than 900° C.

5. The fabrication method of claim 1, wherein the GaN-based semiconductor layer is formed at a temperature between 850˜1050° C.

6. The fabrication method of claim 1, wherein the ZnO-based semiconductor layer is formed on a different bulk substrate.

7. The fabrication method claim 6, wherein the different bulk substrate includes sapphire, silicon carbide, magnesium oxide, gallium oxide, lithium gallium oxide, lithium aluminum oxide, spinel, silicon, germanium, gallium arsenide, gallium phosphide, glass or zirconium diboride.

8. The fabrication method claim 6, wherein the bulk substrate further includes a patterned surface.

9. The fabrication method of claim 1, wherein the ZnO-based semiconductor layer is a single crystal ZnO bulk substrate.

10. The fabrication method of claim 1, wherein the step of forming the transition layer further comprises forming the wetting layer on the ZnO-based semiconductor layer at a first temperature, and nitrifying the wetting layer at a second temperature.

11. The fabrication method of claim 10, wherein the second temperature is not less than the first temperature.

12. The fabrication method of claim 1, wherein the ZnO-based semiconductor layer further includes a patterned surface.

13. A fabrication method of gallium nitride (GaN)-based compound semiconductors, comprising the steps of:
providing a zinc oxide (ZnO)-based semiconductor layer;
forming a first transition layer on the ZnO-based semiconductor layer;
forming a second transition layer on the first transition layer; and
forming a GaN-based semiconductor layer on the second transition layer.

14. The fabrication method of claim 13, wherein the step of forming the first transition layer further comprises repeatly forming a first wetting layer and nitrifying the first wetting layer for many times.

15. The fabrication method of claim 13, wherein the steps of forming the second transition layer further comprises repeatly forming a second wetting layer and nitrifying the second wetting layer for many times.

16. The fabrication method of claim 13, wherein the second transition layer is formed at a temperature not less than a temperature of forming the first transition layer.

17. The fabrication method of claim 14, wherein the first wetting layer is formed by using a trimethylaluminum, trimethylgallium, trimethylindium, triethylaluminum, triethylgallium or triethylalindium reaction precursor.

18. The fabrication method of claim 15, wherein the second wetting layer is formed by using a trimethylaluminum, trimethylgallium, trimethylindium, triethylaluminum, triethylgallium or triethylalindium reaction precursor.

19. The fabrication method of claim 13, wherein wetting layers are nitrided by using an ammonia gas, dimethylhydrazine or tert-butylhydrazine reaction precursor and formed on the first transition layer and the second transition layer.

20. The fabrication method of claim 13, wherein the ZnO-based semiconductor layer further includes a patterned surface.

21. The fabrication method of claim 13, wherein the ZnO-based semiconductor layer is formed on a patterned bulk substrate.

22. A fabrication method of gallium nitride (GaN)-based compound semiconductors, comprising the step of:
providing a sapphire substrate;
forming a zinc oxide (ZnO)-based semiconductor layer on the sapphire substrate;
forming a transition layer on the ZnO-based semiconductor layer;
forming a non-doped GaN-based semiconductor layer on the transition layer;
forming a N-type doped GaN-based ohm contact layer on the non-doped GaN-based semiconductor layer;
forming a light emitting layer of an InGN multiple quantum well structure on the N-type doped GaN-based ohm contact layer;
forming a P-type doped AlGaN cladding layer on the light emitting layer of the InGN multiple quantum well structure; and
forming a P-type doped GaN-based ohm contact layer on the P-type doped AlGaN cladding layer.

23. The fabrication method of claim 22, wherein the step of forming the transition layer further comprises the step of forming a wetting layer on the ZnO-based semiconductor layer by using a reaction precursor selected from the group consisting of trimethylaluminum, trimethylgallium, trimethylindium, triethylaluminum, triethylgallium and triethylalindium.

24. The fabrication method of claim 23, wherein the step of forming the transition layer on the wetting layer further comprises the step of nitrifying the wetting layer by using a reaction precursor selected from the group consisting of ammonia gas, dimethylhydrazine and tert-butylhydrazine.
